(19) United States
(12) Patent Application Publication
(10) Pub. No.: US 2026/0054325 A1
(43) Pub. Date: Feb. 26, 2026

(54) SUBSTRATE PROCESSING METHOD AND SUBSTRATE PROCESSING APPARATUS

(71) Applicant: SEMES CO., LTD., Cheonan-si (KR)

(72) Inventors: Young Dae CHUNG, Incheon (KR); Tae Shin Kim, Suwon-si (KR); Seryeyohan Cho, Daejeon (KR)

(73) Assignee: SEMES CO., LTD., Cheonan-si (KR)

(21) Appl. No.: 19/304,191

(22) Filed: Aug. 19, 2025

(30) Foreign Application Priority Data
Aug. 23, 2024 (KR) 10-2024-0113251

(51) Int. Cl. B23K 26/362; B23K 26/06; B23K 26/0622; B23K 26/08; B23K 26/402; B23K 26/70; B23K 103/00; H01L 21/306; H01L 21/67

(52) U.S. Cl. CPC B23K 26/362; B23K 26/0622; B23K 26/0643; B23K 26/0823; B23K 26/402; H01L 21/30604; H01L 21/6708; B23K 26/704; B23K 2103/56

(57) ABSTRACT

Disclosed is a substrate processing method including: supplying a processing liquid onto a rotating substrate; and irradiating, by the laser irradiation assembly, the rotating substrate, on which a liquid film of the processing liquid is formed, with a laser to heat the substrate, in which the substrate is divided into one or more unit irradiation areas, the laser irradiation assembly designates any one of the one or more unit irradiation areas and irradiates the designated unit irradiation area with the laser, and synchronizes an oscillation frequency of the laser with a rotation speed of the substrate so that an irradiation position of the laser is the designated unit irradiation area.

### CROSS-REFERENCE TO RELATED APPLICATION

This application claims priority to and the benefit of Korean Patent Application No. 10-2024-0113251 filed in the Korean Intellectual Property Office on Aug. 23, 2024, the entire contents of which are incorporated herein by reference.

### TECHNICAL FIELD

The present invention relates to a substrate processing method and a substrate processing apparatus, and more particularly, to a method and apparatus for processing a substrate by irradiating the substrate with a laser.

### BACKGROUND ART

To manufacture a semiconductor device or liquid crystal display, various processes, such as photolithography, etching, ashing, ion implantation, thin film deposition, and cleaning, are performed on a substrate. Among them, the etching process or cleaning process is a process of removing unnecessary areas in a thin film formed on the substrate, requiring high selectivity, high etch rate, and etch uniformity for the thin film, and increasingly higher levels of etch selectivity and etch uniformity are required due to the high integration of semiconductor devices.

In the process of etching the substrate, a processing liquid may be supplied to the substrate to etch a thin film formed on the substrate, and light may irradiate an upper surface of the substrate on which the liquid film is formed by the processing liquid to heat a specific area of the substrate. The entire pattern on the substrate is etched by the processing liquid, but the specific area irradiated with light may be heated to be further etched.

In this case, a method of modulating light using an optical modulation element, such as a Digital Micro-mirror Device (hereinafter referred to as a DMD), and forming an irradiation pattern and irradiating the substrate is used. The degree of etching depends on the amount of heat transmitted by light per unit time, and since DMD may form various forms of irradiation patterns, etching of the substrate W may be controlled in various forms.

Recently, as substrate W stack and bonding technology are advanced, precise dispersion control of the substrate is required for substrate bonding. However, in the case of the process of polishing the substrate, such as the CMP process, it is possible to perform fine polishing on the front of the substrate, but there is a problem that selective polishing on the local area of the substrate is impossible. In addition, a method of selectively and locally heating the substrate W by irradiating some areas of the substrate in a stopped state with light has been disclosed, but when light is emitted to a substrate in a stopped state, the substrate cannot be heated at the same time as the process involving the rotation of the substrate, so there is a problem that the process efficiency decreases.

### SUMMARY OF THE INVENTION

The present invention has been made in an effort to provide a substrate processing method and a substrate processing apparatus capable of effectively processing a substrate.

The present invention has also been made in an effort to provide a substrate processing method and a substrate processing apparatus capable of controlling local etching dispersion in an asymmetric area.

The present invention has also been made in an effort to provide a substrate processing method and a substrate processing apparatus capable of adjusting a shape or distribution of a laser irradiating a substrate to a desired shape or distribution.

The present invention has also been made in an effort to provide a substrate processing method and a substrate processing apparatus capable of performing precise heating on a rotating substrate.

The objectives of the present disclosure are not limited thereto and other objectives not stated herein may be clearly understood by those skilled in the art from the following description.

An exemplary embodiment of the present invention, a substrate processing method comprising: supplying a processing liquid onto a rotating substrate; and irradiating, by the laser irradiation assembly, the rotating substrate, on which a liquid film of the processing liquid is formed, with a laser and heating the substrate, wherein the substrate is divided into one or more unit irradiation areas, the laser irradiation assembly designates any one of the one or more unit irradiation areas and irradiates the designated unit irradiation area with the laser, and synchronizes an oscillation frequency of the laser with a rotation speed of the substrate so that an irradiation position of the laser may be the designated unit irradiation area.

According to the exemplary embodiment of the present invention, the laser irradiation assembly modulates the laser by an optical modulation unit and then irradiates the designated unit irradiation area on the rotating substrate.

According to the exemplary embodiment of the present invention, the optical modulation unit obtains a map of required heating amount distribution within the designated unit irradiation area based on a substrate surface profile for the designated unit irradiation area, and may modulates the laser to correspond to the map of the required heating amount distribution.

According to the exemplary embodiment of the present invention, the optical modulation unit is a Digital Micromirror Device (DMD) unit, and the DMD unit includes micromirrors that are provided to be rotatable, and the modulation of the laser may be performed by adjusting a direction in which each of the micromirrors reflects the laser, and selectively switching between an on state, in which the laser is reflected to irradiate the substrate, and an off state, in which the laser is dumped.

According to the exemplary embodiment of the present invention, when a heat treatment for the designated unit irradiation area is completed by irradiating the designated unit irradiation area with the laser, a target area to be irradiated with the laser is changed from the designated unit irradiation area to another unit irradiation area, and the laser may be modulated and irradiates the other unit irradiation area.

According to the exemplary embodiment of the present invention, when a target area to be irradiated with the laser is changed from the designated unit irradiation area to another unit irradiation area, a delay may be given to the laser.

According to the exemplary embodiment of the present invention, wherein the delay varies may depending on an area of the unit irradiation area or the rotation speed of the substrate.

According to the exemplary embodiment of the present invention, wherein by sequentially modulating the laser and irradiating the one or more unit irradiation areas with the modulated layer, the substrate may be etched by irradiating an entire area of the substrate that requires heating with the laser.

According to the exemplary embodiment of the present invention, wherein the one or more unit irradiation areas may be formed in a fan shape.

According to the exemplary embodiment of the present invention, wherein the one or more unit irradiation areas may be formed to have the same area as each other.

According to the exemplary embodiment of the present invention, wherein each of the laser irradiation assemblies includes a plurality of laser irradiation modules that emits the laser, each of the plurality of laser irradiation modules simultaneously irradiate different areas of the substrate with the laser, respectively, and the areas irradiated by the plurality of laser irradiation modules may combine to form the unit irradiation area.

According to the exemplary embodiment of the present invention, wherein the laser may be output in a form of a pulse.

An exemplary embodiment of the present invention, a substrate processing apparatus comprising: a support unit for supporting a substrate; a liquid supply unit for supplying a processing liquid to the substrate supported by the support unit; a laser irradiation assembly for irradiating the substrate supported by the support unit with a laser; and a controller for controlling the laser irradiation assembly, wherein the laser irradiation assembly includes: a laser source for generating a laser; and a plurality of laser irradiation modules for emitting the laser, and the substrate is divided into one or more unit irradiation areas, and the controller controls the laser irradiation assembly to irradiate a designated unit irradiation area among the one or more unit irradiation areas of the rotating substrate with the laser, and synchronize an oscillation frequency of the laser with a rotation speed of the substrate so that an irradiation position of the laser may be the designated unit irradiation area.

According to the exemplary embodiment of the present invention, wherein the laser irradiation module includes a Digital Micromirror Device (DMD) unit, which is an optical modulation unit that modulates the laser generated from the laser source, and the DMD unit includes: micromirrors that are provided to be rotatable; and a board substrate on which the micromirrors are installed, and the controller may controls the laser irradiation module to modulate the laser by adjusting a direction in which each of the micromirrors reflects the laser.

According to the exemplary embodiment of the present invention, wherein the laser irradiation assembly further may include a measurement member that detects a surface state of the substrate in real time.

According to the exemplary embodiment of the present invention, wherein each of the plurality of laser irradiation modules is configured to irradiate different areas of the substrate with the laser, respectively, and the areas irradiated by the plurality of laser irradiation modules may combine to form the unit irradiation area.

An exemplary embodiment of the present invention, a substrate processing method comprising: supplying a processing liquid onto a rotating substrate; and irradiating, by the laser irradiation assembly, the rotating substrate, on which a liquid film of the processing liquid is formed, with a laser to heat the substrate, wherein the substrate is divided into a plurality of unit irradiation areas, and the laser irradiation assembly modulates the laser using a Digital Micromirror Device (DMD) unit and then designates one unit irradiation area among the plurality of unit irradiation areas and irradiates the designated unit irradiation area with the laser, and synchronizes an oscillation frequency of the laser with a rotation speed of the substrate so that an irradiation position of the laser may be the designated unit irradiation area.

According to the exemplary embodiment of the present invention, wherein the DMD unit obtains a map of required heating amount distribution within the designated unit irradiation area based on a substrate surface profile for the designated unit irradiation area, and may modulates the laser to correspond to the map of the required heating amount distribution.

According to the exemplary embodiment of the present invention, wherein when a heat treatment for the designated unit irradiation area is completed by irradiating the designated unit irradiation area with the laser, a target area to be irradiated with the laser is changed from the designated unit irradiation area to another unit irradiation area, and the laser is modulated and irradiates the another unit irradiation area, and by sequentially modulating the laser and irradiating the one or more unit irradiation areas with the modulated layer, the substrate may be etched by irradiating the entire area of the substrate that requires heating with the laser.

According to the exemplary embodiment of the present invention, wherein each of the plurality of unit irradiation areas may be formed in a fan shape.

According to the exemplary embodiment of the present invention, it is possible to effectively process the substrate.

In addition, according to the exemplary embodiment of the present invention, it is possible to control local etching dispersion in the asymmetric area.

In addition, according to the exemplary embodiment of the present invention, it is possible to adjust a shape or distribution of the laser irradiating the substrate to a desired shape or distribution.

In addition, according to the exemplary embodiment of the present invention, it is possible to perform precise heating on a rotating substrate.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a top plan view of a substrate processing apparatus according to an exemplary embodiment of the present invention.

FIG. 2 is a diagram schematically illustrating a liquid processing chamber of FIG. 1.

FIG. 3 is a diagram illustrating a state in which a laser irradiation assembly of FIG. 2 irradiates a substrate with a laser beam.

FIG. 4 is a diagram schematically illustrating a configuration of a laser irradiation module of FIG. 3.

FIG. 5 is a graph illustrating distribution of light output from a laser source, and FIG. 6 is a graph illustrating distribution of light passing through a beam shaper.

FIG. 7 is a diagram schematically illustrating an optical modulation element.

FIG. 8 is a diagram illustrating a state in which light is output from the optical modulation element.

FIG. 9 is a diagram illustrating a state in which light output from the optical modulation element is removed from an optical dumper.

FIG. 10 is a diagram for describing a principle of removing light from the optical dumper.

FIG. 11 is a diagram for describing an irradiation pattern of light output from the optical modulation unit.

FIG. 12 is an exemplary diagram illustrating a substrate processing method according to an exemplary embodiment of the present invention.

FIG. 13 is a diagram schematically illustrating the liquid processing chamber when a processing liquid supplying step of FIG. 12 is performed.

FIG. 14 is a diagram schematically illustrating a liquid processing chamber when a substrate is irradiated with a laser using the laser irradiation assembly.

FIG. 15 is a diagram schematically illustrating a substrate surface profile and unit irradiation areas on a substrate.

FIGS. 16 to 18 are diagrams illustrating a process of irradiating a first irradiation area of a substrate that is supported by a support unit and rotates with a laser.

FIG. 19 is a graph schematically illustrating the intensity of a laser irradiating a first irradiation area over time according to the exemplary embodiment of the present invention.

FIG. 20 is a diagram illustrating a state in which a second irradiation area of the substrate is irradiated with a laser.

FIG. 21 is a graph schematically illustrating the intensity of a laser irradiating the second irradiation area over time according to the exemplary embodiment of the present invention.

FIG. 22 is a diagram illustrating a state in which a laser irradiates an N^{th} irradiation area of the substrate.

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a process of etching a substrate using a processing liquid and a laser will be described as an example. However, the present exemplary embodiment is not limited to the etching process, and may be applied in various ways in a substrate processing process using a liquid, such as a cleaning process, an ashing process, and a development process.

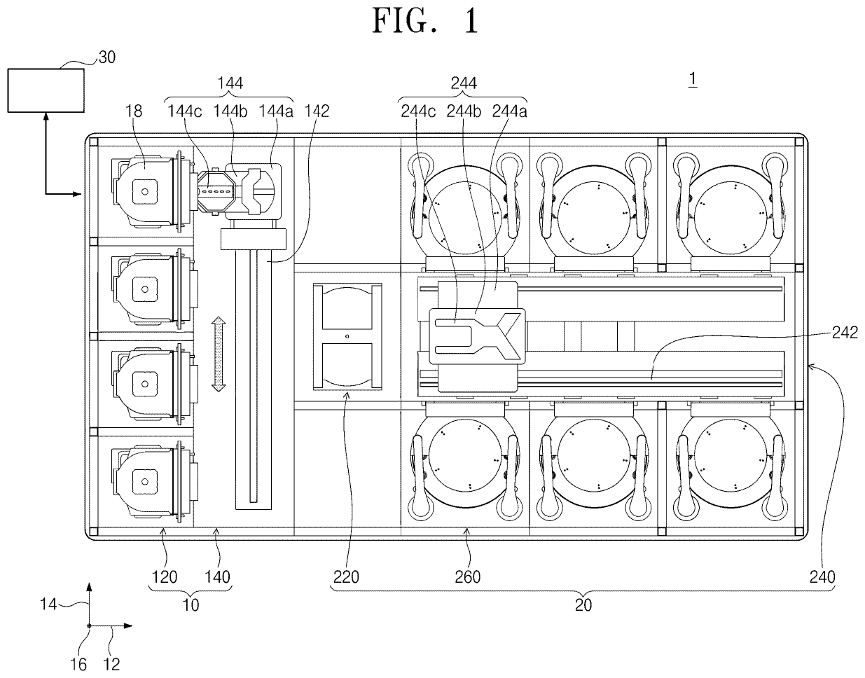

Hereinafter, an exemplary embodiment of the present invention will be described with reference to FIGS. 1 to 22.

FIG. 1 is a top plan view of a substrate processing apparatus according to an exemplary embodiment of the present invention. Referring to FIG. 1, a substrate processing apparatus includes an index module 10, a process processing module 20, and a controller 30. The index module 10 includes a load port 120 and a transfer frame 140. The load port 120, the transfer frame 140, and the processing module 20 are sequentially arranged in a line. Hereinafter, a direction in which the load port 120, the transfer frame 140, and the process processing module 20 are arranged is referred to as a first direction 12, a direction perpendicular to the first direction 12 is referred to as a second direction 14, and a direction perpendicular to the plane, including the first direction 12 and the second direction 14, is referred to as a third direction 16.

A carrier 130 in which the substrate W is accommodated is seated on the load port 120. A plurality of load ports 120 is provided, and they are arranged in a line along the second direction 14. The number of load ports 120 may increase or decrease according to the process efficiency and footprint conditions of the process processing module 20. A plurality of slots (not illustrated) for accommodating the substrates W in a state of being horizontally arranged with respect to the ground is formed in the carrier 130. A Front Opening Unified Pod (FOUP) may be used as the carrier 130.

The process processing module 20 includes a buffer unit 220, a transfer chamber 240, and a process chamber 260. A longitudinal direction of the transfer chamber 240 is disposed parallel to the first direction 12. Process chambers 260 are disposed on opposite sides of the transfer chamber 240, respectively. On one side and the other side of the transfer chamber 240, the process chambers 260 are provided to be symmetrical with respect to the transfer chamber 240. A plurality of process chambers 260 is provided on one side of the transfer chamber 240. Some of the process chambers 260 are disposed along the longitudinal direction of the transfer chamber 240. In addition, some of the process chambers 260 are arranged to be stacked on each other. That is, the process chambers 260 may be arranged in A×B arrangement at one side of the transfer chamber 240. Herein, A is the number of process chambers 260 provided in a row along the first direction 12, and B is the number of process chambers 260 provided in a row along the third direction 16. When four or six process chambers 260 are provided at one side of the transfer chamber 240, the process chambers 260 may be arranged in 2×2 or 3×2 arrangement. The number of process chambers 260 may increase or decrease. Unlike the above description, the process chamber 260 may be provided only at one side of the transfer chamber 240. Also, the process chamber 260 may be provided as a single layer at one side and opposite sides of the transfer chamber 240.

The buffer unit 220 is disposed between the transfer frame 140 and the transfer chamber 240. The buffer unit 220 provides a space in which the substrate W stays before the substrate W is transferred between the transfer chamber 240 and the transfer frame 140. A slot (not illustrated) in which the substrate W is placed is provided in the buffer unit 220. A plurality of slots (not illustrated) is provided to be spaced apart from each other along a third direction 16. The buffer unit 220 has an open surface facing the transfer frame 140 and an open surface facing the transfer chamber 240.

The transfer frame 140 transfers the substrate W between the carrier 130 seated on the load port 120 and the buffer unit 220. An index rail 142 and an index robot 144 are provided in the transfer frame 140. The index rail 142 is provided with a longitudinal direction parallel to the second direction 14. The index robot 144 is installed on the index rail 142 and moves linearly in the second direction 14 along the index rail 142. The index robot 144 has a base 144a, a body 144b, and an index arm 144c. The base 144a is installed to be movable along the index rail 142. The body 144b is coupled to the base 144a. The body 144b is provided on the base 144a to be movable along the third direction 16. In addition, the body 144b is provided to be rotatable on the base 144a. The index arm 144c is coupled to the body 144b and is provided to be able to move forward and backward with respect to the body 144b. A plurality of index arms 144c is provided to be individually driven. The index arms 144c are disposed to be stacked while being spaced apart from each other along the third direction 16. A portion of the index arms 144c may be used to transfer the substrate W from the process processing module 20 to the carrier 130, and another portion thereof may be used to transfer the substrate W from the carrier 130 to the process processing module 20. This may prevent particles generated from the substrate W before the process processing from adhering to the substrate W after the process processing in a process in which the index robot 144 loads and unloads the substrate W.

The transfer chamber 240 transfers the substrate W between the buffer unit 220 and the process chamber 260 and between the process chambers 260. A guide rail 242 and a main robot 244 are provided in the transfer chamber 240. The guide rail 242 is arranged such that its longitudinal direction is parallel to the first direction 12. The main robot 244 is installed on the guide rail 242, and moves linearly along the first direction 12 on the guide rail 242. The main robot 244 includes a base 244a, a body 244b, and a main arm 244c. The base 244a is installed to be movable along the guide rail 242. The body 244b is coupled to the base 244a. The body 244b is provided on the base 244a to be movable along the third direction 16. Furthermore, the body 244b is provided on the base 244a to be rotatable. The main arm 244c is coupled to the body 244b, which is provided to be movable forward and backward with respect to the body 244b. A plurality of index arms 244c is provided to be individually driven. The index arms 244c are disposed to be stacked while being spaced apart from each other along the third direction 16.

The process chamber 260 is provided to a liquid processing chamber 300 that rotates the substrate W in a horizontal position and supplies a processing liquid to the rotating substrate W to process the substrate W.

The controller 30 may control components of the substrate processing apparatus 1. The controller 30 may include a process controller formed of a microprocessor (computer) that executes the control of the substrate processing apparatus, a user interface formed of a keyboard in which an operator performs a command input operation or the like in order to manage the substrate processing apparatus, a display for visualizing and displaying an operation situation of the substrate processing apparatus, and the like, and a storage unit storing a control program for executing the process executed in the substrate processing apparatus under the control of the process controller or a program, that is, a processing recipe, for executing the process in each component according to various data and processing conditions. Further, the user interface and the storage unit may be connected to the process controller. The processing recipe may be stored in a storage medium in the storage unit, and the storage medium may be a hard disk, and may also be a portable disk, such as a CD-ROM or a DVD, or a semiconductor memory, such as a flash memory.

The controller 30 may control the substrate processing apparatus 1 to perform the substrate processing method described below. For example, the controller 30 may control the components provided to a liquid processing chamber 300 so as to perform the substrate processing method described below.

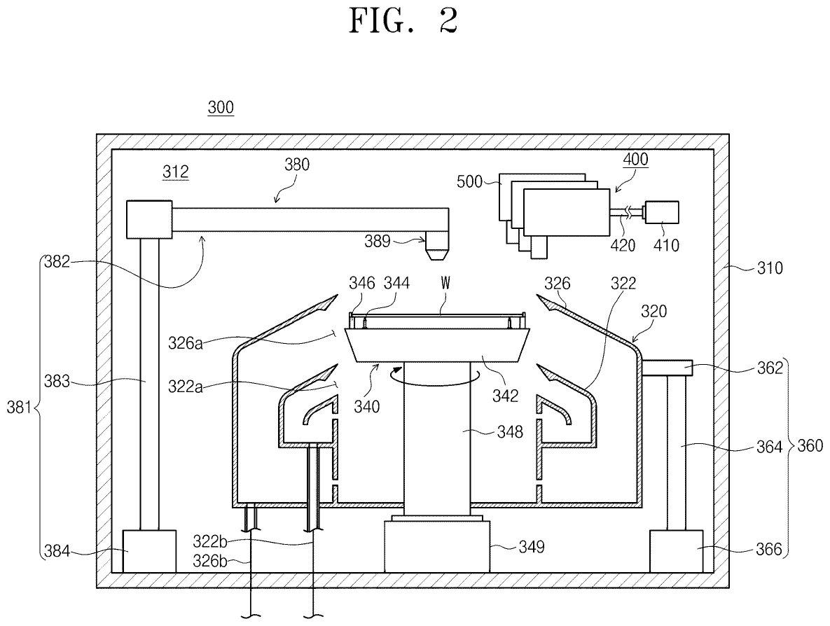

FIG. 2 is a diagram schematically illustrating the liquid processing chamber of FIG. 1.

Referring to FIG. 2, the liquid processing chamber 300 may include a housing 310, a cup 320, a support unit 340, a lifting unit 360, a liquid supply unit 380, and a laser irradiation assembly 400.

The housing 310 has a processing space 312 therein. The housing 310 may have a cylindrical shape having a space therein. The cup 320, the support unit 340, the lifting unit 360, the liquid supply unit 380, and the laser irradiation assembly 400 may be provided in the processing space 312 of the housing 310. The housing 310 may have a rectangular shape when viewed from a front cross-section. However, the present invention is not limited thereto, and the housing 310 may be modified into various shapes which may have the processing space 312.

The cup 320 has a cylindrical shape with an open top. The cup 320 has an internal recovery container 322 and an external recovery container 326. Each of the recovery containers 322 and 326 recovers different processing liquids among processing liquids used in the process. The internal recovery container 322 is provided in a ring shape surrounding the support unit 340 of the substrate W, and the external recovery container 326 is provided in a ring shape surrounding the internal recovery container 322. The inner space 322a of the internal recovery container 322 and the internal recovery container 322 function as a first inlet 322a through which the processing liquid is introduced into the internal recovery container 322. The space 326a between the internal recovery container 322 and the external recovery container 326 functions as a second inlet 326a through which the processing liquid is introduced into the external recovery container 326. According to an example, the respective inlets 322a and 326a may be positioned at different heights. Recovery lines 322b and 326b are connected below the bottom surfaces of the recovery containers 322 and 326, respectively. The processing liquids introduced into the recovery containers 322b and 326b may be provided to an outside processing liquid regeneration system (not illustrated) through the recovery lines 322b and 326b, respectively, and may be reused.

The support unit 340 supports the substrate W in the processing space 3121. The supporting unit 340 supports and rotates the substrate W during the process. The supporting unit 340 includes a support plate 342, a support pin 344, a chuck pin 346, and rotation driving members 348 and 349.

The support plate 342 is provided in a generally circular plate shape, and has an upper surface and a lower surface. The lower surface has a smaller diameter than the upper surface. That is, the support plate 342 may have a shape having a wide upper surface and a narrow lower surface. The upper and lower surfaces are positioned so that their central axes coincide with each other.

A plurality of support pins 344 is provided. The support pins 344 are disposed on the edge of the upper surface of the support plate 342 to be spaced apart from each other at a predetermined interval and protrude upward from the support plate 342. The support pins 344 are arranged to have an annular ring shape as a whole by combination therebetween. The support pin 344 supports the rear edge of the substrate W so that the substrate W is spaced apart from the upper surface of the support plate 342 by a predetermined distance.

A plurality of chuck pins 346 is provided. The chuck pin 346 is disposed to be farther from the center of the support plate 342 than the support pin 344. The chuck pin 346 is provided to protrude upward from the upper surface of the support plate 342. The chuck pin 346 supports a side portion of the substrate W so that the substrate W is not separated from a regular position in a lateral direction when the support plate 342 is rotated. The chuck pin 346 is provided to be linearly moved between an outer position and an inner position in a radial direction of the support plate 342. The outer position is a position farther from the center of the support plate 342 than the inner position. When the substrate W is loaded on or unloaded from the support plate 342, the chuck pin 346 is positioned at the outer position, and the chuck pin 346 is positioned at the inner position when the process is performed on the substrate W. The inner position is a position where the chuck pin 346 and the side portion of the substrate W are in contact with each other, and the outer position is a position where the chuck pin 346 and the substrate W are spaced apart from each other.

The rotation driving members 348 and 349 rotate the support plate 342. The support plate 342 is rotatable with respect to a magnetic central axis by the rotation driving members 348 and 349. The rotation driving members 348 and 349 include a support shaft 348 and a driving unit 349. The support shaft 348 has a cylindrical shape. An upper end of the support shaft 348 is fixedly coupled to a bottom surface of the support plate 342. According to an example, the support shaft 348 may be fixedly coupled to a center of a bottom surface of the support plate 342. The driving unit 349 provides driving force to rotate the support shaft 348. The support shaft 348 is rotated by the driving unit 349, and the support plate 342 is rotatable together with the support shaft 348.

The lifting unit 360 linearly moves the cup 320 in the up and down direction. As the cup 320 is moved up and down, a relative height of the cup 320 with respect to the support plate 342 is changed. When the substrate W is loaded onto the support plate 342 or unloaded, the lifting unit 360 descends the cup 320 such that the support plate 342 protrudes upward from the cup 320. Also, when the process is performed, the height of the cup 320 is adjusted so that the processing liquid may be introduced into the preset recovery containers 322 and 326 according to the type of processing liquid supplied to the substrate W. The lifting unit 360 includes a bracket 362, a moving shaft 364, and a driver 366. The bracket 362 is fixedly installed on the outer wall of the cup 320, and a moving shaft 364 that moves in the up and down direction by the driver 366 is fixedly coupled to the bracket 362. Selectively, the lifting unit 360 may move the support plate 342 in the up and down direction.

The liquid supply unit 380 may supply a processing liquid to the substrate W. The liquid supply unit 380 may include a moving member 381 and a nozzle 389. The liquid supply unit 380 may pump and transfer the processing liquid stored in a storage tank (not illustrated) and discharge the processing liquid to the substrate W through the nozzle 389. The processing liquid may be an organic solvent, the chemical or rinse liquid. The organic solvent may be an isopropyl alcohol (IPA) liquid.

The processing liquid supplied from the liquid supply unit 380 to the substrate W may vary depending on the substrate processing process. For example, when the substrate processing process is a silicon nitride film etching process, the processing liquid may be chemical including phosphoric acid (H₃PO₄).

The liquid supply unit 380 may further include a rinse liquid R supply nozzle for rinsing the surface of the substrate after performing an etching process, an isopropyl alcohol (IPA) discharge nozzle and a nitrogen (N₂) discharge nozzle to perform a drying process after rinsing. The rinse liquid may be deionized water (DIW). Although only one nozzle 389 is illustrated in FIG. 2, the number of nozzles 389 may be provided in a number corresponding to the number of types of discharged liquid.

The moving member 381 moves the nozzle 389 to a process position and a standby position. The process position is a position at which the nozzle 389 is opposite to the substrate W supported by the support unit 340. According to an example, the process position is a position at which the processing liquid is discharged on the upper surface of the substrate W. In addition, the process position includes a first supply position and a second supply position. The first supply position may be a position closer to the center of the substrate W than the second supply position, and the second supply position may be a position including the end of the substrate W. Optionally, the second supply position may be an area adjacent to the end of the substrate W. The standby position is defined as a position at which the nozzle 389 is out of the process position. According to an example, the standby position may be a position at which the nozzle 389 waits before or after the process is completed on the substrate W.

The moving member 381 includes an arm 382, a support shaft 383, and a driver 384. The support shaft 383 may be positioned at one side of the cup 320. The support shaft 383 has a rod shape of which a longitudinal direction thereof faces a fourth direction. The support shaft 383 is provided to be rotatable by the driver 384. The support shaft 383 is provided to be movable upward and downward. The arm 382 is coupled to an upper end of the support shaft 383. The arm 382 vertically extends from the driver 384. The nozzle 389 is coupled to an end of the arm 382. As the support shaft 383 is rotated, the nozzle 389 may be swing-moved together with the arm 382. The nozzle 389 may be swing-moved to the process position and the standby position. Selectively, the arm 382 may be provided to be moved forward and backward in a longitudinal direction thereof. When viewed from above, a path through which the nozzle 389 moves may coincide with a central axis of the substrate W at the process position.

The laser irradiation assembly 400 may irradiate the substrate W with the laser L.

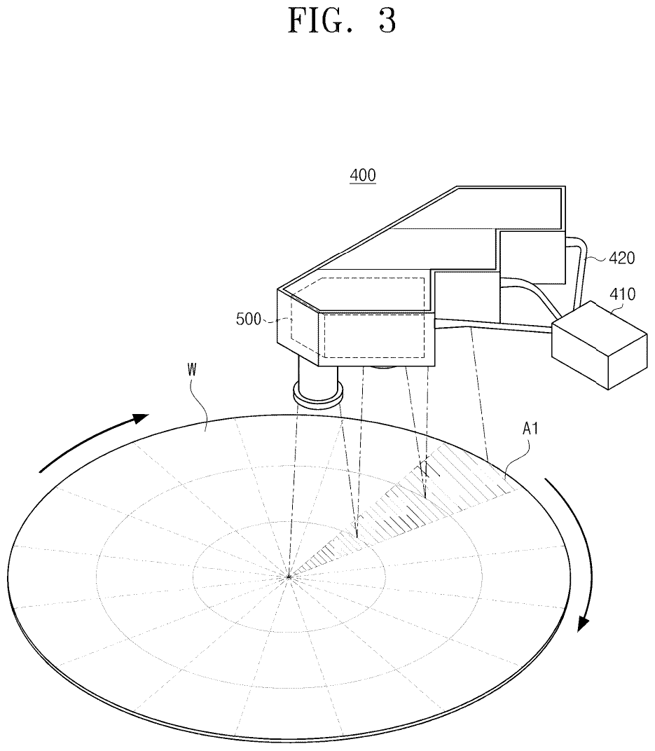

FIG. 3 is a diagram illustrating a state in which the laser irradiation assembly of FIG. 2 irradiates a substrate with a laser beam. Referring to FIGS. 2 and 3, the laser irradiation assembly 400 may heat the substrate W by irradiating the substrate W having a liquid film formed on the upper surface thereof by a processing liquid (e.g., an etching liquid) supplied by the liquid supply unit 380 with a laser. The temperature of the area of the substrate W irradiated with the laser L emitted by the laser irradiation assembly 400 may increase. Accordingly, etching may be relatively further performed in the area which is irradiated with the laser L, and etching may be relatively less performed in the area which is not irradiated with the laser L.

The laser irradiation assembly 400 includes a laser source 410, a laser transmission member 420, and a plurality of laser irradiation modules 500.

The laser source 410 may generate the laser L. The laser source 410 may generate the laser L having straightness. The laser L generated by the laser source 410 may irradiate the substrate W to heat the substrate W. The laser L may be a laser beam, a fiber laser, a laser diode, or the like. The laser source 410 may generate the laser L with an output capable of properly driving the optical modulation unit 540 without damage.

The laser transmission member 420 transmits the laser L generated from the laser source 410 to the laser irradiation module 500. According to an example, the laser transmission member 420 may be an optical fiber.

The laser irradiation assembly 400 may be fixedly installed inside the liquid processing chamber 300. Hereinafter, the present invention will be described based on the case where the laser irradiation assembly 400 is fixedly installed above the support unit 340 in the liquid processing chamber 300 and is provided to irradiate the substrate W supported by the support unit 340 with the laser L as an example. However, unlike this, a driving unit (not illustrated) that is movable between a position where the laser L irradiates the substrate W supported by the support unit 340 and the standby position may be further included.

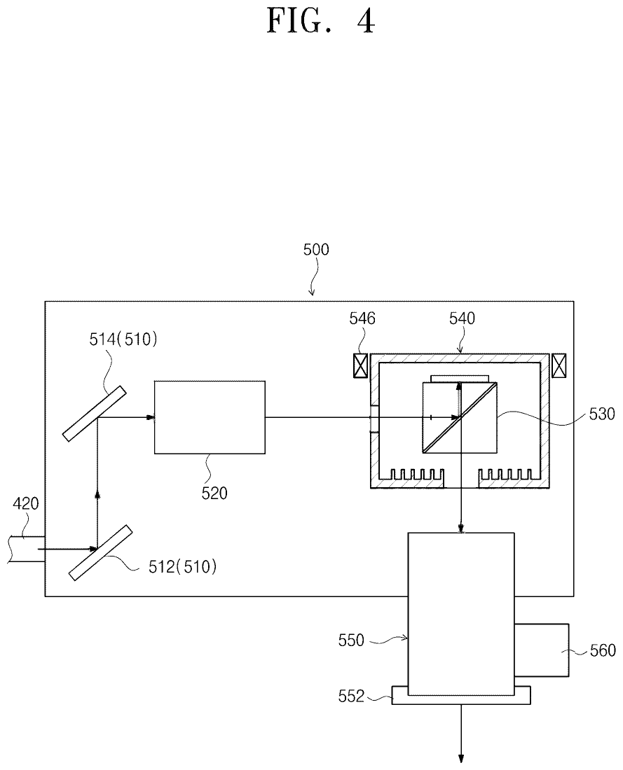

FIG. 4 is a diagram schematically illustrating a configuration of the laser irradiation module of FIG. 3.

The laser irradiation module 500 includes a mirror 510, a beam shaper 520, an optical instrument 530, an optical modulation unit 540, an imaging unit 550, and a measurement member 560.

The mirror 510 reflects the laser L incident on the laser irradiation module 500 through the laser transmission member 420 and transmits the reflected laser L to the beam shaper 520. The mirror 510 may include a plurality of mirrors for appropriately reflecting the path of the laser L. For example, the mirror 510 may include a first mirror 512 and a second mirror 514.

The beam shaper 520 may convert a form of light output from the laser source 410.

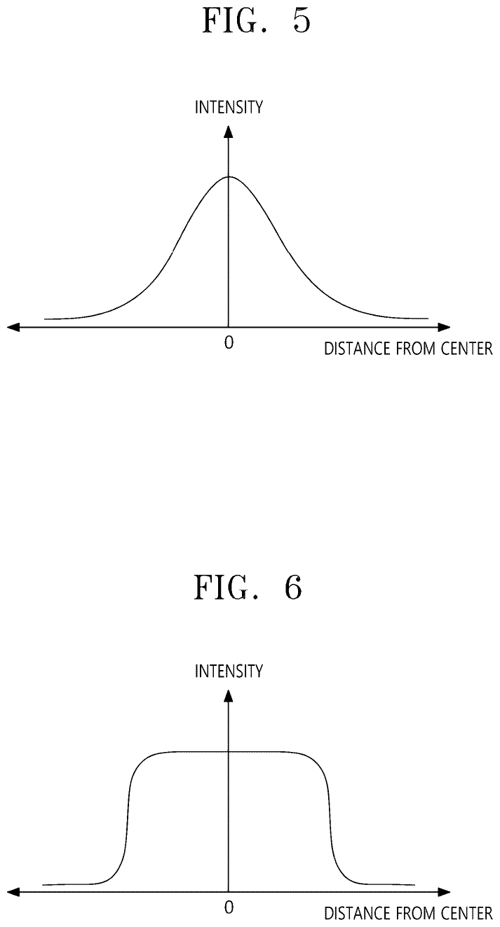

FIG. 5 is a graph illustrating distribution of light output from the laser source, and FIG. 6 is a graph illustrating distribution of light passing through the beam shaper.

Referring to FIGS. 4 to 6, the laser L output from the laser source 410 may have a Gaussian form in which an intensity distribution has the Gaussian distribution as illustrated in FIG. 6. More specifically, the intensity of the laser L output from the laser source 410 is greater at the center of the laser L, and the intensity thereof may gradually decrease as the laser L moves away from the center of the L beam (see FIG. 5). Accordingly, when the substrate W is irradiated with the laser L output from the laser source 410, an area close to the center of the laser L may be further heated, and an area close to the edge of the laser L may be less heated. Accordingly, when the laser L is transmitted to the optical modulation element 542 to be described later, light is transmitted to a portion of the optical modulation element 542 corresponding to the center portion of the laser L more than necessary, thereby causing damage to the optical modulation element 542, while light is not sufficiently transmitted to a portion of the optical modulation element 542 corresponding to the edge of the laser L, and thus the optical modulation efficiency of the optical modulation element 542 may be reduced.

Accordingly, in the laser irradiation unit 500 according to the exemplary embodiment of the present invention, the beam shaper 520 may be disposed on the traveling path of the laser L output from the laser source 410. The beam shaper 520 may convert the Gaussian-shaped laser L output from the laser source 410 into the flat-top-shaped laser L. The laser L output from the laser source 410 may be converted into a flat top form in which intensity (luminosity) distribution is relatively uniform through the beam shaper 520 (see FIG. 6). Since the laser L of the flat top form is modulated by the optical modulation element 452, utilization and optical modulation efficiency of the optical modulation element 452 may be improved.

Referring back to FIG. 4, the laser L passing through the beam shaper 520 may be transmitted to the optical instrument 530.

The optical instrument 530 may reflect the laser L that has passed through the beam shaper 520 again to the optical modulation unit 540. The optical instrument 530 may be a prism or a mirror. The optical instrument 540 may be applied in various configurations capable of transmitting the laser L reflected by the first mirror 531 to the optical modulation unit 540. The laser L transmitted to the optical modulation unit 540 may be modulated by the optical modulation unit 540 and outputted. The laser L modulated and output by the optical modulation unit 540 may pass through the optical instrument 530 and be transmitted to the imaging unit 550.

The optical modulation unit 540 may modulate the transmitted laser L. The optical modulation unit 540 may include the optical modulation element 542, the optical dumper 544, and the cooling instrument 546.

The optical modulation element 542 may modulate the distribution of the laser L generated by the laser source 410. Here, modulating the distribution of the laser L may be forming the distribution of the laser L corresponding to the irradiation pattern of the laser L to irradiate the substrate W.

The optical modulation element 542 may be a Digital Micro-mirror Device (DMD).

That is, the optical modulation unit 540 may be a DMD unit including a DMD.

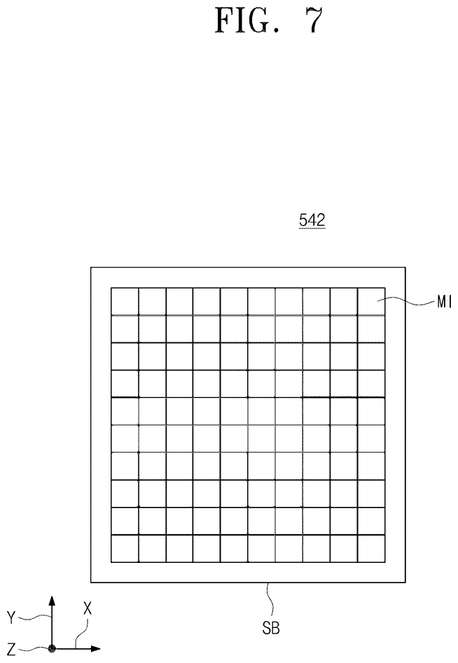

FIG. 7 is a diagram schematically illustrating the optical modulation element. Referring to FIG. 7, the optical modulation element 542 may include a board substrate SB and a plurality of micromirrors MI. Electrodes respectively corresponding to the plurality of micromirrors MIs may be installed on the board substrate SB. The controller 30 may transmit a digital signal of “0” or “1” to an electrode installed on the board substrate SB. The micromirrors MIs may be rotatably configured. The micromirrors MIs may be rotatably configured with respect to the first direction X, the second direction Y, or a direction parallel to a plane passing through the first direction X and the second direction Y as a rotation axis. The micromirror MI corresponding to the electrode to which the digital signal of “0” has been transmitted may be in an off state, and the micromirror MI corresponding to the electrode to which the digital signal of “1” has been transmitted may be in an on state. The on-state micromirror MI may irradiate the substrate W with the laser L, and the substrate W may not be irradiated with the laser L reflected by the off-state micromirror MI.

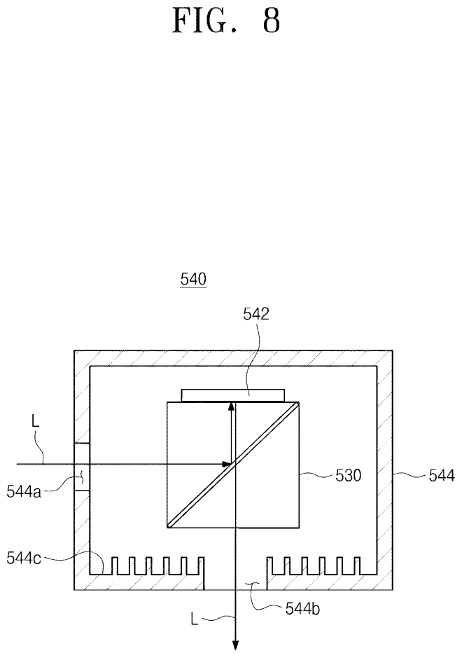

FIG. 8 is a diagram illustrating a state in which light is output from the optical modulation element. For convenience of description, FIG. 8 illustrates a traveling path of light reflected by any one of the micromirrors MI. Referring to FIGS. 4, 7, and 8, the laser L reflected by the on-state micromirror MI may be output and transmitted to the substrate W through the imaging unit 550 to be described later.

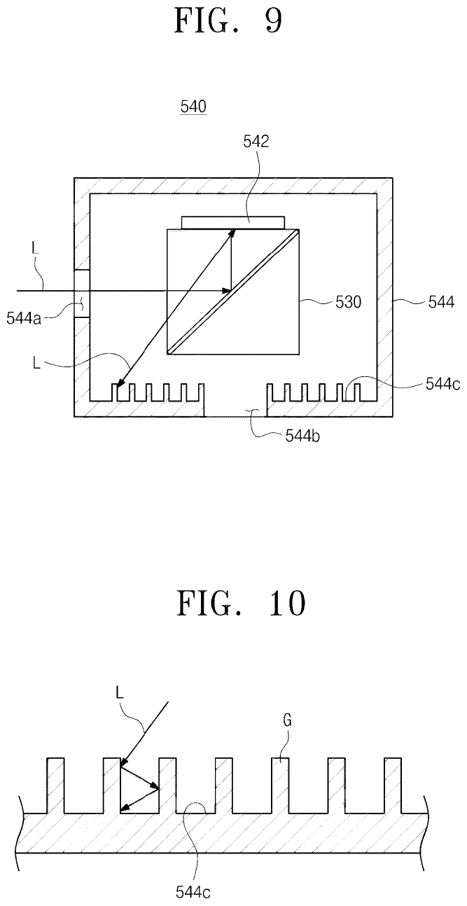

FIG. 9 is a diagram illustrating a state in which light output from the optical modulation element is removed from the optical dumper. For convenience of description, FIG. 9 illustrates a traveling path of the laser L reflected by any one of the micromirrors MI. Referring to FIGS. 4, 7, and 9, the micromirror MI that is in the off state may reflect the laser L and may not transmit the laser L to the substrate W. Specifically, the micromirror MI is configured to be rotatable as described above. The off-state micromirror MI may rotate to change a traveling path of the laser L transmitted from the laser source 410 so that light is not transmitted to the substrate W. The laser L emitted from the off-state micromirror MI may not pass through a second hole 554b of the optical dumper 544 to be described later and may irradiate the inner side surface of the optical dumper 544 to be extinguished.

FIG. 10 is a diagram for describing a principle of removing light from the optical dumper. Referring to FIGS. 4 and 10, the optical dumper 544 may have a cylindrical shape having an inner space. The optical dumper 544 may be made of a material, such as synthetic resin, that may absorb and remove the laser L. The optical instrument 540 may be disposed in the inner space of the optical dumper 544. The optical modulation element 542 may be disposed in the inner space of the optical dumper 544 or may be installed outside the optical dumper 544.

The optical dumper 544 may be formed with a first hole 544a and a second hole 554b. The first hole 544a may be formed on a side portion of the optical dumper 544. The first hole 544a may be a hole through which the laser L generated by the laser source 410 and converted through the beam shaper 520 passes. The second hole 554b may be a hole through which the laser L modulated by the optical modulation element 544 passes. The second hole 554b may be formed under the optical dumper 544.

A groove G may be formed on the inner side surface 554c of the optical dumper 544. The groove G formed on the inner side surface 554c of the optical dumper 461 may be configured to absorb light reflected by the off-state micromirror MI. Specifically, when the laser L is transmitted to the groove G, the laser L may be removed while being reflected in the groove G several times. The laser L may be removed while being reflected several times in the groove G and losing thermal energy to the optical dumper 544. Although FIG. 4 and FIG. 10 illustrate that the groove G is formed only in the lower portion of the optical dumper 544, the present invention is not limited thereto, and the groove G may be formed over the entire inner surface 554c of the optical dumper 544.

Referring back to FIG. 4, as the optical dumper 544 removes the laser L, the temperature of the optical dumper 544 may increase. Accordingly, the optical modulation unit 540 according to the exemplary embodiment of the present invention may include the cooling instrument 544 for cooling the optical dumper 546. The cooling instrument 546 may be a fan forming an airflow for cooling the optical dumper 544.

The imaging unit 550 may irradiate the substrate W with the laser L that has been modulated and output by the optical modulation unit 540 and passed through the optical instrument 530 by adjusting the laser L to correspond to the area to be irradiated. The imaging unit 550 includes a plurality of lenses capable of adjusting the size of the laser L, and may adjust the profile of the laser L irradiating to the substrate W by expanding or reducing the diameter of the laser L.

The imaging unit 550 may include a configuration for removing a noise pattern from diffraction patterns output from the optical modulation unit 540. For example, the imaging unit 550 may include a spatial filter.

The imaging unit 550 includes an irradiation lens 552. The laser L modulated and output by the optical modulation unit 540 and passing through the optical instrument 530 is adjusted by the imaging unit 550 and irradiates the substrate W through the irradiation lens 552.

Although not illustrated as an exemplary embodiment, the irradiation lens 552 may include a plurality of lenses, and may be provided to change a relative distance between a plurality of lenses forming the irradiation lens 552, so that the area which is irradiated with the laser L may be adjusted.

The measurement member 560 measures a state of the substrate W in real time. The measurement member 560 may be attached to and installed on one side of the laser irradiation module 500. Alternatively, the measurement member 560 may be provided to the laser irradiation assembly 400 or may be fixedly installed in the liquid processing chamber 300. The state of the substrate W measured by the measurement member 560 may mean a state of the surface of the substrate W or data on an etching amount required for each area of the substrate W. The measurement member 560 may include a sensor that optically measures a distance. According to an example, the measurement member 560 may include a chromatic confocal sensor. The measurement member 560 may measure the distance from the measurement member 560 to the surface of the substrate W in real time, and may scan and/or analyze the surface of the substrate W to represent the scanned and/or analyzed surface of the substrate W as a 2D distribution profile.

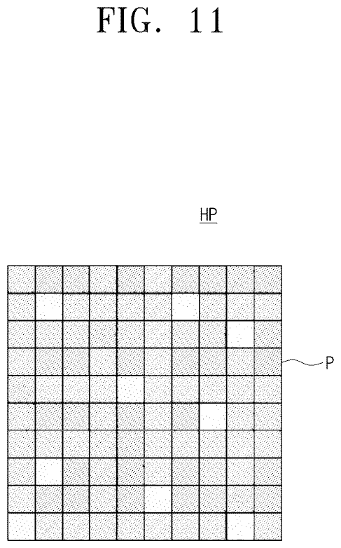

FIG. 11 is a diagram for describing an irradiation pattern of light output from the optical modulation unit. Referring to FIGS. 4, 7, and 11, as described above, the micromirror MI may be switched between an on-state and an off-state. Switching between the on-state and the off-state of each micromirror MI may be performed within a very short time. According to the switching between the on state and the off state of each micromirror MI, the optical modulation unit 540 may form a wide variety of irradiation patterns HPs. For example, FIG. 11 illustrates the amount of heat transferred to the substrate W by the laser L reflected from each micromirror MI for a unit time (e.g., 1 second) per unit time. The irradiation pattern HP may include a plurality of patterns P corresponding to the micromirrors MIs, respectively. In order to increase the amount of heat transferred to the substrate W per unit time in each micromirror MI, the on-state of the micromirror MI per unit time may be maintained long and the off-state may be maintained short. In order to reduce the amount of heat transferred to the substrate W per unit time in each micromirror MI, the on-state of the micromirror MI per unit time may be maintained short and the off-state may be maintained long.

Referring back to FIG. 3, the laser L modulated in the optical modulation unit 540 of the laser irradiation module 500 and adjusted in the imaging unit 550 is emitted to the substrate W. In this case, the substrate W may be divided into one or more unit irradiation areas. FIG. 3 illustrates the laser irradiation assembly 400 irradiating the first irradiation area A1 of the rotating substrate W with the laser L. The first irradiation area A1 is an example of a unit irradiation area obtained by randomly dividing the substrate W requiring heating. The shape and size of the unit irradiation area may be variously modified. Hereinafter, for convenience of description, the entire area (area requiring heating) of the substrate W is equally divided into n fan-shaped unit irradiation areas having the same inscribed angle. One of the n equally divided unit irradiation areas is named as a first irradiation area A1, and then other irradiation areas adjacent to the first irradiation area A1 are sequentially named as a second irradiation area A2, a third irradiation area A3 to an nth irradiation area An, and a substrate processing method according to an exemplary embodiment in which the substrate W is composed of n unit irradiation areas will be described.

Each of the plurality of laser irradiation modules 500 of the laser irradiation assembly 400 may irradiate the laser L onto the substrate W. Each of the plurality of laser irradiation modules 500 may irradiate a portion of the unit irradiation area of the corresponding substrate W with the laser L. Each of the plurality of laser irradiation modules 500 may be configured so that the areas irradiated with the laser L do not overlap each other. The laser L area irradiated from each of the plurality of laser irradiation modules 500 may be combined to form a unit irradiation area. That is, the laser irradiation assembly 400 may irradiate the unit irradiation area on the substrate W with the laser L as the plurality of laser irradiation modules 500 simultaneously irradiate different areas of the substrate W with the laser L, respectively.

As illustrated in FIG. 3, the case where the laser irradiation assembly 400 includes three laser irradiation modules 500 is exemplified as an example for convenience of description. The laser irradiation modules 500 simultaneously irradiate different areas of the substrate W with the laser L, respectively. The laser L emitted from each laser irradiation module 500 is combined to form the first irradiation area A1. In other words, the laser irradiation assembly 400 may irradiate the first irradiation area A1 with the laser L.

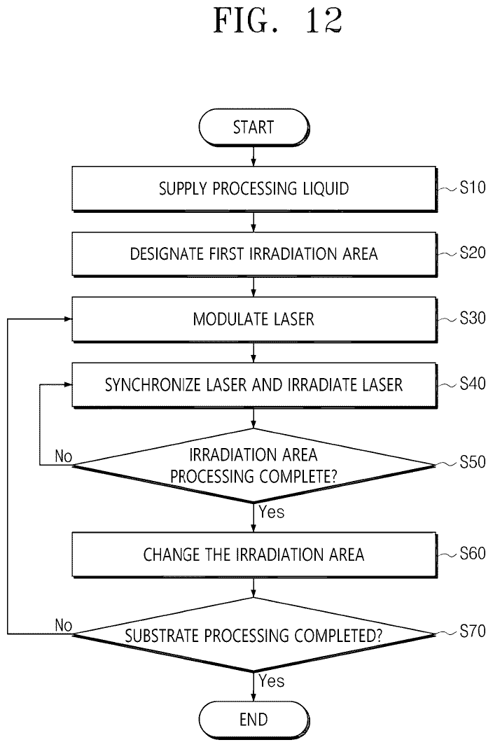

FIG. 12 is an exemplary diagram illustrating a substrate processing method according to an exemplary embodiment of the present invention.

Hereinafter, a substrate processing method according to an exemplary embodiment of the present invention will be described with reference to FIGS. 12 to 22. Since the substrate processing method described below is performed in the substrate processing apparatus 1 described above, reference numerals cited in FIGS. 1 to 11 are cited in the same manner below. In addition, the substrate processing method according to the following exemplary embodiment may be performed by controlling the components included in the substrate processing apparatus by the controller 30.

The present invention will be described based on the case where the substrate processing method described below is an etching process in which a processing liquid, which is an etchant, is supplied to the substrate W and the substrate W is heated and etched as an example.

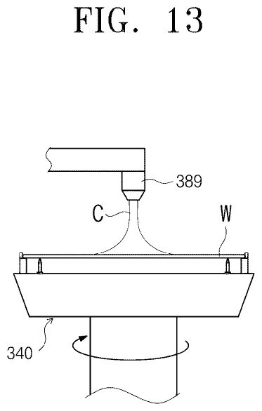

Referring to FIG. 12, in the substrate processing method according to the exemplary embodiment, a processing liquid is first supplied onto a rotating substrate W (S10). FIG. 13 is a diagram schematically illustrating the liquid processing chamber when the processing liquid of FIG. 12 is supplied. Referring further to FIG. 13, in the processing liquid supply S10, a processing liquid C is supplied to the rotating substrate W. The processing liquid C may be supplied from the nozzle 389.

When the processing liquid C is supplied to the rotating substrate W, the processing liquid C may be supplied in an amount sufficient to form a liquid film or a puddle. For example, the amount of processing liquid C supplied to the substrate W may cover the entire upper surface of the substrate W, but may be supplied such that the amount of the processing liquid C does not flow from the substrate W or the amount of processing liquid C flowing down is not large even if the processing liquid C flows down. If necessary, the processing liquid C may be supplied to the entire upper surface of the substrate W while changing the position of the nozzle 389 to form a liquid film or a puddle on the substrate W.

When a liquid film is formed on the substrate W after the processing liquid supply S10 is performed, a process of heating the substrate W by irradiating the rotating substrate W with the laser L is performed.

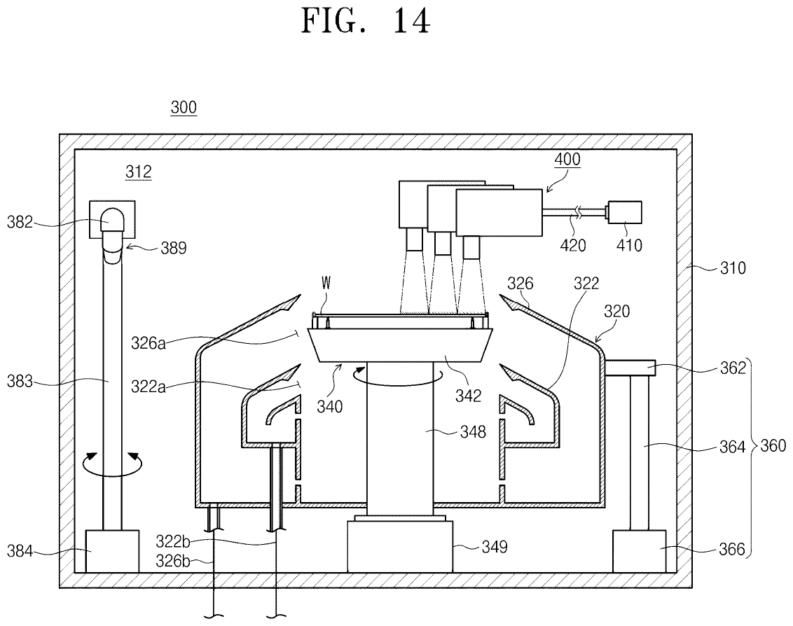

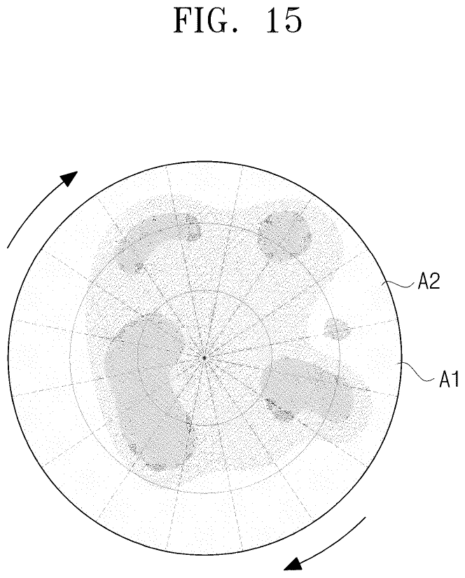

FIG. 14 is a diagram schematically illustrating the liquid processing chamber when the substrate is irradiated with a laser using the laser irradiation assembly. In an operation of heating the substrate W using the laser irradiation assembly 400, the laser irradiation assembly 400 designates a unit irradiation area of the substrate W to be irradiated with the laser L (S20), modulates the laser L to correspond to the designated unit irradiation area (S30), and irradiates the designated unit irradiation area with the laser L having a frequency synchronized with a rotation speed of the substrate W (S40).

It is determined whether the heat treatment is completed for the designated unit irradiation area (S50), and if not, the laser L having the frequency synchronized with the rotation speed of the substrate W may be continuously emitted to the designated unit irradiation area. When the heat treatment is completed for the designated unit irradiation area, an area to be irradiated with the laser L is changed to another unit irradiation area on the substrate W (S60), and the laser L is modulated to correspond to the changed unit irradiation area (S30), and the laser L having the frequency synchronized with the rotation speed of the substrate W is emitted to the designated unit irradiation area (S40).

When the heat treatment on the substrate W is completely completed by sequentially modulating and emitting the laser L to all unit irradiation areas configured on the substrate W as described above (S70), the process of processing the substrate W, for example, the etching process for the substrate W, may be terminated.

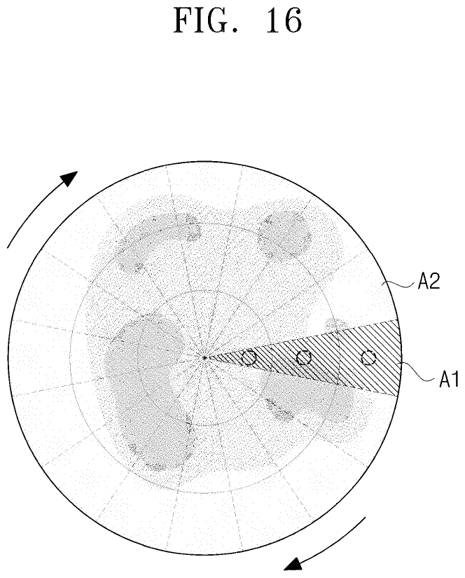

Hereinafter, the operation of heating the substrate W using the laser irradiation assembly 400 described above will be described in more detail with reference to FIGS. 15 to 22.

FIG. 15 is a diagram schematically illustrating a substrate surface profile and unit irradiation areas on a substrate. As illustrated in FIG. 15, a map of required heating amount distribution for the entire area of the substrate may be obtained by using profile data for the surface of the substrate. A profile for the surface of the substrate may be measured from the measurement member 560. Alternatively, a profile for the surface of the substrate may be obtained through a separate inspection process on the substrate W before the substrate W is loaded into the liquid processing chamber 300. In FIG. 15, for convenience of description, the state of the surface of the substrate is displayed in different colors. For example, the area marked dark on the substrate W illustrated in FIG. 15 may mean a point where a required etching amount is relatively high, that is, a point where an amount of heating using the laser L is relatively high. Also, the area marked light on the substrate W illustrated in FIG. 15 may mean a point where a required etching amount is relatively low, that is, a point where an amount of heating using the laser L is relatively low.

As described above, in FIG. 15, boundary lines which equally divides the entire area of the substrate W into fan-shaped unit irradiation areas having the same inscribed angle is illustrated, and among the equally divided unit irradiation areas, the first irradiation area A1 and the second irradiation area A2, which is another irradiation area adjacent to the first irradiation area A1, are displayed.

In the step of heating the substrate W using the laser irradiation assembly 400, the laser irradiation assembly 400 designates a unit irradiation area of the substrate W to be irradiated with the laser L (S20). In this case, for convenience of description, the present invention will be described based on the case where the first irradiation area A1 is designated as an example.

FIGS. 16 to 18 are diagrams illustrating a process of irradiating the first irradiation area of the substrate that is supported by the support unit and rotates with a laser.

Referring to FIG. 16, the laser irradiation assembly 400 modulates the distribution of the laser L to correspond to the first irradiation area A1 (S30), and irradiates the first irradiation area A1 with the laser L (S40). That is, the laser irradiation assembly 400 forms a laser distribution corresponding to an irradiation pattern of the laser L to be emitted to the first irradiation area A1 by using the map of the required heating amount distribution obtained from profile data of the first irradiation area A1, and the first irradiation area A1 is irradiated with the corresponding irradiation pattern. Hereinafter, the irradiation of the irradiation patterns by modulating the distribution of the laser L will be briefly described in that the laser irradiation assembly 400 and the laser irradiation module 500 irradiate the substrate W with the laser L.

The three laser irradiation modules 500 included in the laser irradiation assembly 400 simultaneously irradiate different areas within the first irradiation area A1 of the substrate W with the laser L.

In FIG. 16, the substrate W is divided into three areas along the radial direction, and to illustrate that each laser irradiation modules 500 one-to-one corresponds with the three areas, the center of the imaging unit 550 of each laser irradiation module 500 is projected and the circles are illustrated in dotted lines when viewed from above.

As illustrated in FIG. 16, since the areas corresponding to each of the three laser irradiation modules 500 are combined to form the first irradiation area A1, when each laser irradiation module 500 modulates the distribution of the laser L in the optical modulation unit 540 and irradiates the modulated laser L to the corresponding area, the laser L may irradiate the entire first irradiation area A1.

In this case, the laser irradiation assembly 400 is fixedly installed above the support unit 340, and the substrate W continues to rotate, so that the irradiation position of the laser L becomes the first irradiation area A1, which is the designated unit irradiation area, it is necessary to synchronize the oscillation frequency of the laser L with the rotation speed of the substrate W.

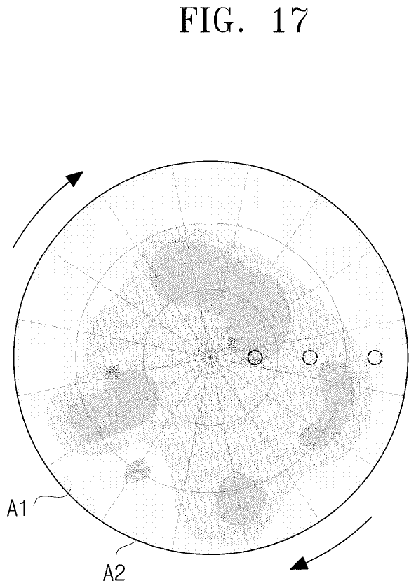

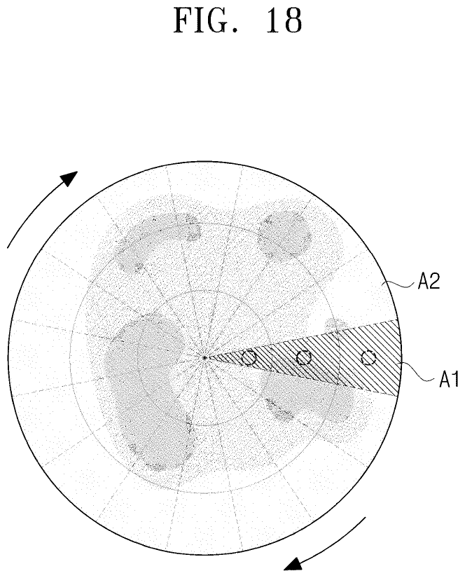

That is, as illustrated in FIG. 17, when the first irradiation area A1 is not located under the laser irradiation assembly 400, the laser irradiation assembly 400 is controlled not to irradiate the substrate W with the laser L.

In addition, as illustrated in FIGS. 16 and 18, the laser irradiation assembly 400 is controlled to irradiate the substrate W the laser L when the substrate W is rotated and the first irradiation area A1 is located under the laser irradiation assembly 400.

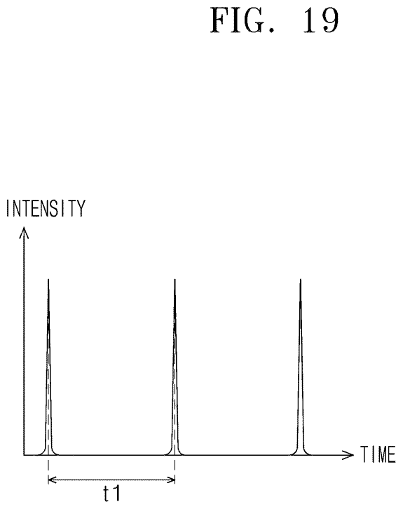

FIG. 19 is a graph schematically illustrating the intensity of a laser irradiating the first irradiation area over time according to the exemplary embodiment of the present invention. Referring to FIG. 19, the laser L irradiating the first irradiation area A1 in the laser irradiation assembly 400 has a period of t1.

Since the oscillation frequency of the laser L is synchronized with the rotation speed of the substrate W, for example, when the rotation speed of the substrate W supported by the support unit 340 is 300 rpm, the oscillation frequency of the laser L may be 5 Hz and t1 may be 0.2 s.

The laser L may be emitted in a pulse form. That is, the laser L may be a pulse laser. When the laser L having a short pulse width is emitted, when the laser irradiation assembly 400 irradiates the first irradiation area A1 of the substrate W with the laser L, irradiation of an adjacent unit irradiation area with the laser L may be minimized.

In this way, the first irradiation area A1 is designated (S20), the laser L is modulated to correspond to the first irradiation area A1 (S30), and when the laser L of the frequency synchronized with the rotation speed of the substrate W irradiates the first irradiation area A1 (S40), and the heating to the first irradiation area A1 may be completed. The process S50 of determining whether the heat treatment for the first irradiation area A1 is completed may be performed based on data obtained by measuring the surface state of the substrate W in real time by the measurement member 560.

When it is determined that the heat treatment for the first irradiation area A1 is completed, the unit irradiation area to be irradiated with the laser L is changed from the first irradiation area A1 to another unit irradiation area (S60), and the series of processing steps S20 to S50 described above are sequentially performed.

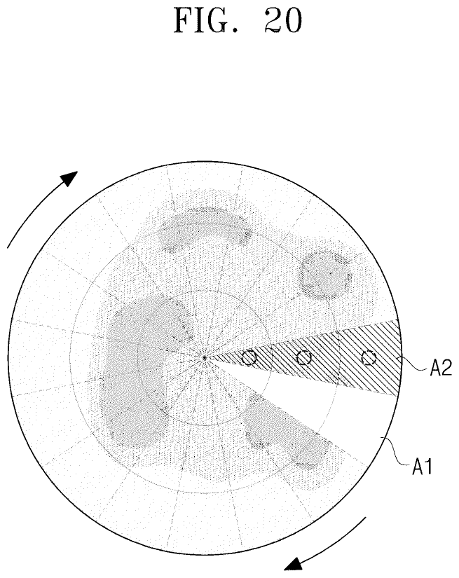

FIG. 20 is a diagram illustrating a state in which the second irradiation area of the substrate is irradiated with a laser. Referring to FIG. 20, when it is determined that the heat treatment for the first irradiation area A1 is completed, the unit irradiation area to be irradiated with the laser L is changed from the first irradiation area A1 to the second irradiation area A2 (S60).

The laser irradiation assembly 400 modulates the distribution of the laser L to correspond to the second irradiation area A2 (S30), and irradiates the second irradiation area A2 with the laser L (S40). That is, the laser irradiation assembly 400 forms a laser distribution corresponding to the irradiation pattern of the laser L to be emitted to the second irradiation area A2 by using the required heating amount data obtained from profile data of the second irradiation area A2, and irradiates the second irradiation area A2 with the corresponding irradiation pattern.

As in the case of the first irradiation area A1 described above, the laser irradiation assembly 400 is controlled to irradiate the substrate W the laser L when the substrate W rotates and the second irradiation area A2 is located under the laser irradiation assembly 400.

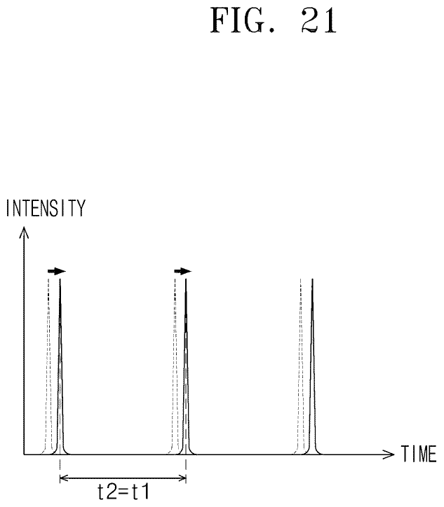

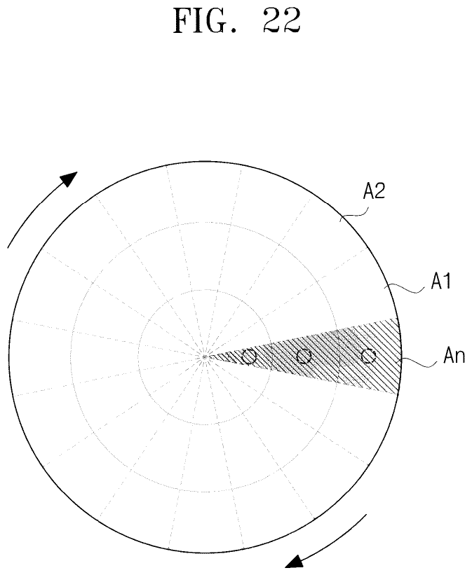

FIG. 21 is a graph schematically illustrating the intensity of a laser irradiating the second irradiation area over time according to the exemplary embodiment of the present invention.

Referring to FIG. 21, the laser L pulse irradiating the first irradiation area A1 is illustrated by a dotted line, and the laser L pulse irradiating the second irradiation area A2 is illustrated by a solid line. The laser irradiation assembly 400 may provide a delay to the laser L so as to irradiate the second irradiation area A2 with the laser L that has irradiated the first irradiation area A1. The delay may vary according to the area of the unit irradiation area formed on the substrate W or the rotation speed of the substrate. The delay may be the shortest time of the time from the time when the first irradiation area A1 is located under the laser irradiation assembly 400 to the time when the second irradiation area A2 is located under the laser irradiation assembly 400.

For example, when the substrate W is divided into n unit irradiation areas as the exemplary embodiment illustrated in FIG. 20, the delay given by the laser irradiation assembly 400 to change the laser L irradiating to the first irradiation area A1 to the second irradiation area A2 is the same as the time it takes for the substrate W to rotate 1/n of a turn. This is because when the substrate W rotates 1/n of a turn, the unit irradiation area located under the laser irradiation assembly 400 is changed from the first irradiation area A1 to the second irradiation area A2.

The laser L irradiating the second irradiation area A2 by the laser irradiation assembly 400 has a period of t2.

Since the oscillation frequency of the laser L is synchronized with the rotation speed of the substrate W, for example, when the rotation speed of the substrate W supported by the support unit 340 is 300 rpm, the oscillation frequency of the laser L may be 5 Hz and t2 may be 0.2 s. When the substrate W rotates at the same speed during the process of irradiating and heating the substrate W with the laser L, t2 is the same as t1 of FIG. 19.

In this way, when the unit irradiation area irradiated with the laser L is changed from the first irradiation area A1 to the second irradiation area A2 (S60), the laser L is modulated to correspond to the second irradiation area A2 (S30), and the laser L of a frequency synchronized with the rotation speed of the substrate W irradiates the second irradiation area A2 (S40), heating to the second irradiation area A2 may be completed. The process of determining whether the heat treatment on the second irradiation area A2 is completed (S50) may be performed by measuring the surface state of the substrate W in real time by the measurement member 560.

When it is determined that the heat treatment for the second irradiation area A2 is completed, the unit irradiation area to be irradiated with the laser L is changed from the second irradiation area A2 to another unit irradiation area (S60), and a series of processing steps S20 to S50 are sequentially performed.

FIG. 22 is a diagram illustrating a state in which a laser irradiates an Nth irradiation area of the substrate.

All unit irradiation areas configured on the substrate W are sequentially irradiated with the laser L by modulating the laser L, and when it is determined that the heat treatment for the N^{th} irradiation area An is completed (S70), heating and etching for the entire area requiring heating of the substrate W is completed. Accordingly, the etching process for the substrate W is terminated.

According to the exemplary embodiment, after the etching process for the substrate W is completed, a process of cleaning the substrate W by supplying the rinse liquid R to the substrate W may be further included. The rinse liquid R may be supplied to the substrate W from a nozzle (not illustrated). More specifically, the rinse liquid R is supplied to the rotating substrate W, and the rinse liquid R supplied to the substrate W removes the etching impurities generated during the process of performing the above-described etching process from the substrate W. Also, the rinse liquid R may replace the liquid film formed on the substrate W to clean the substrate W.

According to the exemplary embodiment of the present invention, the substrate W may be divided into a plurality of unit irradiation areas, and the laser L may be modulated according to heating required amount distribution data for each unit irradiation area to be emitted. Since the optical modulation unit 540 may form an irradiation pattern having various shapes according to the heating required amount distribution data expressed as a 2D profile within the unit irradiation area, the temperature distribution within the local area of the substrate W may be controlled, and local etching dispersion control for the asymmetric area of the substrate W is possible, so that the substrate may be effectively etched according to a desired shape. For this reason, it is possible to increase the efficiency of a process requiring precise dispersion control of the substrate W, such as substrate bonding.

According to the exemplary embodiment of the present invention, the substrate W is divided into fan-shaped unit irradiation areas, and each unit irradiation area is irradiated with a laser L. As the unit irradiation area is formed in a fan-shaped shape, even if the laser L irradiates the unit irradiation area of the rotating substrate W, the irradiation is not affected by the difference in angular velocity between the central portion and the edge portion of the substrate W. Accordingly, the local area of the substrate W may be precisely heated, and the precision of etching the substrate W may be increased.

According to the exemplary embodiment of the present invention, the laser irradiation assembly 400 includes a plurality of laser irradiation modules 500, and each laser irradiation module 500 irradiates different areas with the laser L, but combines the irradiated areas to form one unit irradiation area. One laser irradiation module 500 irradiates only a partial area of the substrate W with the laser L, and the laser irradiation assembly 400 also sequentially irradiates each unit irradiation area of the substrate W to heat the entire substrate W. Accordingly, it is possible to design a device that is free from the limit of the output of the laser L or the limit of damage to the optical modulation element 542, and it is also possible to achieve the miniaturization of the device.

According to the exemplary embodiment of the present invention, the fixed laser irradiation assembly 400 emits the laser L and synchronizes the laser L oscillation frequency with the rotation speed of the substrate W, thereby maintaining the same position on the rotating substrate W irradiated with the laser L. Therefore, precise heating may be performed while the rotating substrate W is irradiated with the laser L.

In addition, since the irradiation position of the laser L on the substrate W may be changed in a simple way to give delay to the laser L, the substrate processing apparatus and the substrate processing method that may etch the entire surface of the substrate W without moving the unit emitting the laser L or changing the path of the laser L by using optical equipment, such as a lens, may be provided.

In the above-described exemplary embodiment, it has been described on the premise that the rotation speed of the substrate W is constant while the substrate W is heated. However, unlike this, the rotation speed of the substrate W may be changed during the process of etching the substrate W as necessary, and the oscillation frequency of the laser L irradiating the substrate W may be synchronized with the changed rotation speed of the substrate W.

In the above-described exemplary embodiment, it has been illustrated and described that three laser irradiation modules 500 are included in one laser irradiation assembly 400. However, unlike this, the number of laser irradiation modules may be provided in various numbers within the scope of the purpose intended to be achieved by the present invention.

In the above-described exemplary embodiment, it is described that the plurality of laser irradiation modules 500 irradiates different areas with the laser L so that the areas irradiated with the laser L do not overlap. However, when the laser L needs to be overlapped, such as when the laser output is limited or when the amount of required heating is large, some or all of the areas irradiated with the laser L by the plurality of laser irradiation modules 500 may overlap.

In the above-described exemplary embodiment, for convenience of description, the entire area of the substrate W is illustrated and described as a fan-shaped unit irradiation area. However, unlike this, the unit irradiation area may be configured in a free shape and size on the substrate W.

In the above-described exemplary embodiment, for convenience of description, it has been illustrated and described that the entire area of the substrate W is equally divided into n parts, and the shapes and sizes of the unit irradiation areas are the same. However, unlike this, each unit irradiation area may have different shapes and sizes, and the optical modulation unit 540 may modulate the laser L to correspond to the shape and size of the corresponding unit irradiation area.

In the above-described exemplary embodiment, it has been illustrated and described that the substrate is heated by sequentially irradiating the adjacent unit irradiation area with the laser. However, unlike this, the substrate may be heated by irradiating random unit irradiation areas located discontinuously with the laser as necessary.

In the above-described exemplary embodiment, it has been illustrated and described that the entire area of the substrate W is heated by sequentially irradiating the unit irradiation area. However, unlike this, the substrate may be treated by selectively heating only a partial area of the substrate W as needed.

In the above-described exemplary embodiment, it has been illustrated and described that the processing liquid is supplied to the substrate W and then the substrate W is heated, but the present invention is not limited thereto. The substrate W may be heated while the processing liquid is supplied to the substrate W.

In the above exemplary embodiment, a case where the substrate W processed in the liquid processing chamber 300 is a wafer has been described as an example, but the present invention is not limited thereto. For example, the substrate may be provided as various types and shapes of substrates requiring etching or adjustment of pattern line widths, such as a photo mask, a glass substrate, and a metal film, which are ‘frames’ used in an exposure process.

It should be understood that exemplary embodiments are disclosed herein and other modifications may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present disclosure, and all such modifications that would be obvious to one of ordinary skill in the art are intended to be included within the scope of the accompanying claims.

1. A substrate processing method comprising:
supplying a processing liquid onto a rotating substrate; and
irradiating, by the laser irradiation assembly, the rotating substrate, on which a liquid film of the processing liquid is formed, with a laser to heat the substrate,
wherein the substrate is divided into one or more unit irradiation areas,
the laser irradiation assembly designates any one of the one or more unit irradiation areas and irradiates the designated unit irradiation area with the laser, and synchronizes an oscillation frequency of the laser with a rotation speed of the substrate so that an irradiation position of the laser is the designated unit irradiation area.

2. The substrate processing method of claim 1, wherein the laser irradiation assembly modulates the laser by an optical modulation unit and then irradiates the designated unit irradiation area on the rotating substrate.

3. The substrate processing method of claim 2, wherein the optical modulation unit obtains a map of required heating amount distribution within the designated unit irradiation area based on a substrate surface profile for the designated unit irradiation area, and modulates the laser to correspond to the map of the required heating amount distribution.

4. The substrate processing method of claim 2, wherein the optical modulation unit is a Digital Micromirror Device (DMD) unit, and
the DMD unit includes micromirrors that are provided to be rotatable, and
the modulation of the laser is performed by adjusting a direction in which each of the micromirrors reflects the laser, and selectively switching between an on state, in which the laser is reflected to irradiate the substrate, and an off state, in which the laser is dumped.

5. The substrate processing method of claim 1, wherein when a heat treatment for the designated unit irradiation area is completed by irradiating the designated unit irradiation area with the laser,
a target area to be irradiated with the laser is changed from the designated unit irradiation area to another unit irradiation area, and
the laser is modulated and irradiates the other unit irradiation area.

6. The substrate processing method of claim 1, wherein when a target area to be irradiated with the laser is changed from the designated unit irradiation area to another unit irradiation area, a delay is given to the laser.

7. The substrate processing method of claim 6, wherein the delay varies depending on an area of the unit irradiation area or the rotation speed of the substrate.

8. The substrate processing method of claim 6, wherein by sequentially modulating the laser and irradiating the one or more unit irradiation areas with the modulated layer, the substrate is etched by irradiating an entire area of the substrate that requires heating with the laser.

9. The substrate processing method of claim 1, wherein the one or more unit irradiation areas are formed in a fan shape.

10. The substrate processing method of claim 1, wherein the one or more unit irradiation areas are formed to have the same area as each other.

11. The substrate processing method of claim 1, wherein each of the laser irradiation assemblies includes a plurality of laser irradiation modules that emits the laser,
each of the plurality of laser irradiation modules simultaneously irradiate different areas of the substrate with the laser, respectively, and
the areas irradiated by the plurality of laser irradiation modules combine to form the unit irradiation area.

12. The substrate processing method of claim 1, wherein the laser is output in a form of a pulse.

13.-16. (canceled)

17. A substrate processing method comprising:
supplying a processing liquid onto a rotating substrate; and
irradiating, by the laser irradiation assembly, the rotating substrate, on which a liquid film of the processing liquid is formed, with a laser to heat the substrate,
wherein the substrate is divided into a plurality of unit irradiation areas, and
the laser irradiation assembly modulates the laser using a Digital Micromirror Device (DMD) unit and then designates one unit irradiation area among the plurality of unit irradiation areas and irradiates the designated unit irradiation area with the laser, and
synchronizes an oscillation frequency of the laser with a rotation speed of the substrate so that an irradiation position of the laser is the designated unit irradiation area.

18. The substrate processing method of claim 17, wherein the DMD unit obtains a map of required heating amount distribution within the designated unit irradiation area based on a substrate surface profile for the designated unit irradiation area, and modulates the laser to correspond to the map of the required heating amount distribution.

19. The substrate processing method of claim 17, wherein when a heat treatment for the designated unit irradiation area is completed by irradiating the designated unit irradiation area with the laser,
a target area to be irradiated with the laser is changed from the designated unit irradiation area to another unit irradiation area, and
the laser is modulated and irradiates the another unit irradiation area, and
by sequentially modulating the laser and irradiating the one or more unit irradiation areas with the modulated layer, the substrate is etched by irradiating the entire area of the substrate that requires heating with the laser.

20. The substrate processing method of claim 17, wherein each of the plurality of unit irradiation areas is formed in a fan shape.
